(19) United States
(12) Patent Application Publication
(10) Pub. No.: US 2014/0334101 A1
(43) Pub. Date: Nov. 13, 2014

(54) FAN SPEED CONTROL SYSTEM

(71) Applicants: HON HAI PRECISION INDUSTRY CO., LTD., New Taipei (TW); Hong Fu Jin Precision Industry (ShenZhen) Co., Ltd, Shenzhen (CN)

(72) Inventor: MING YU, Shenzhen (CN)

(73) Assignees: HON HAI PRECISION INDUSTRY CO., LTD., New Taipei (TW); Hong Fu Jin Precision Industry (ShenZhen) Co., Ltd, Shenzhen (CN)

(21) Appl. No.: 14/105,180

(22) Filed: Dec. 13, 2013

(30) Foreign Application Priority Data
May 10, 2013 (CN) 2013101706898

(51) Int. Cl. H05K 7/20

(52) U.S. Cl. CPC H05K 7/20209; H05K 7/20136
USPC 361/695

(57) ABSTRACT

A fan speed control system includes a BMC, a CPLD, and a temperature sensor. The BMC includes an operation signal sending pin. The CPLD includes an operation signal receiving pin connected to the operation signal sending pin. The temperature sensor is configured for detecting temperatures of electronic components. When the BMC fails to operate normally, the operation signal sending pin sends a BMC_fail signal to the operation signal receiving pin, the temperature sensor sends the detected temperatures to the CPLD. The CPLD compares the detected temperatures with the corresponding preset standard temperatures and adjusts the speed of the fan module according to a comparing result.

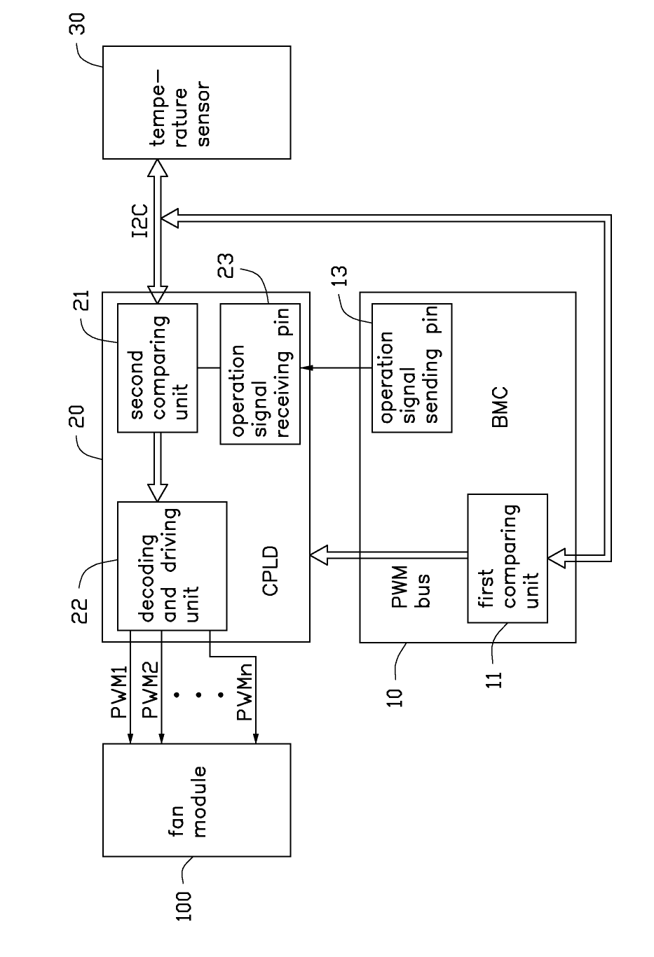

### BACKGROUND

1. Technical Field

The present disclosure relates to control systems, and particularly to a fan speed control system.

2. Description of Related Art

Fans are often used in computer systems to control temperatures of the computer systems, and a Baseboard Management Controller (BMC) may be used to send a Pulse-Width Modulation (PWM) signal to the fans to control speeds of the fans. However, if the BMC fails to operate normally, the speed of the fans cannot be adjusted to control the temperatures of the computer systems. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

The figure is a block diagram of an embodiment of a fan speed control system.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

The figure shows one embodiment of a fan speed control system for controlling a speed of a fan module 100 in an electronic device. The fan control system comprises a BMC 10, a Complex Programmable Logic Device (CPLD) 20, and a temperature sensor 30.

The temperature sensor 30 is used for detecting a temperature of each electronic component in the electronic device and sending a temperature signal to the BMC 10 and the CPLD 20.

The BMC 10 comprises a first comparing unit 11 and an operation signal sending pin 13. An input end of the first comparing unit 11 is connected to the temperature sensor 30 through an I²C bus. An output end of the first comparing unit 11 is connected to the CPLD 20 through a PWM bus. The first comparing unit 11 presets standard temperatures of each electronic component of the electronic device. The first comparing unit 11 compares the temperatures corresponding to the temperature signals with the corresponding standard temperature of the electronic components, and generates a first PWM signal for each electronic component. The first comparing unit 11 further sends the first PWM signal to the CPLD 20. The operation signal sending pin 13 sends a BMC_fail signal to the CPLD 20 when the BMC 10 fails to operate normally.

The CPLD 20 comprises a second comparing unit 21, a decoding and driving unit 22, and an operation signal receiving pin 23. An input end of the second comparing unit 21 is connected to the temperature sensor 30 through the I²C bus. An output end of the second comparing unit 21 is connected to the decoding and driving unit 22. The second comparing unit 21 presets the standard temperatures of the electronic components of the electronic device. The second comparing unit 21 compares the temperatures of the corresponding temperature signals with the corresponding standard temperatures of the electronic component, and then generates a second PWM signal for each electronic component. The second comparing unit 21 further sends the second PWM signal to the decoding and driving unit 22. The decoding and driving unit 22 is connected to the output end of the first comparing unit 11. The decoding and driving unit 22 decodes the first PWM signal or the second PWM signal, and adjusts the speed of the fan module 100 according to the decoded first PWM signal or the decoded second PWM signal. The operation signal receiving pin 23 is connected to the operation signal sending pin 13 and is used for receiving the BMC_fail signal. When the BMC 10 operates normally, the operation signal receiving pin 23 does not receive the BMC_fail signal, and the second comparing unit 21 is switched off. The second comparing unit 21 is switched on when the operation signal receiving pin 23 receives the second comparing unit 21.

In use, when the BMC 10 operates normally, the second comparing unit 21 is switched off. The first comparing unit 11 compares the temperatures corresponding to the temperature signals with the corresponding standard temperatures of the electronic components, and generates the first PWM signals. The first comparing unit 11 sends the first PWM signals to the decoding and driving unit 22. The decoding and driving unit 22 decodes the first PWM signals and adjusts the speed of the fan module 100 according to the decoded first PWM signals.

When the BMC 10 fails to operate normally, the first comparing unit 11 cannot operate normally, and the operation signal sending pin 13 sends the BMC_fail signal to the operation signal receiving pin 23 to switch on the second comparing unit 21. The second comparing unit 21 compares the temperatures corresponding to the temperature signals with the corresponding standard temperatures of the electronic components, and generates the second PWM signals. The second comparing unit 21 sends the second PWM signals to the decoding and driving unit 22. The decoding and driving unit 22 decodes the second PWM signals and adjusts the speed of the fan module 100 according to the decoded second PWM signals.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A fan speed control system, comprising:
a BMC (Baseboard Management Controller) comprising an operation signal sending pin;
a CPLD (Complex Programmable Logic Device) comprising an operation signal receiving pin connected to the operation signal sending pin; and
a temperature sensor is configured for detecting temperatures of electronic components;
wherein when the BMC fails to operate normally, the operation signal sending pin sends a BMC_fail signal to the operation signal receiving pin, the temperature sensor sends the detected temperatures to the CPLD, and the CPLD compares each detected temperature with a corresponding preset temperature and adjusts the speed of a fan module according to a comparing result.

2. The fan speed control system of claim 1, wherein when the BMC operates normally, the temperature sensor sends the detected temperatures to the BMC, and the BMC compares each detected temperature with the corresponding preset temperature and sending a first PWM signal to the CPLD.

3. The fan speed control system of claim 2, wherein the CPLD is configured for decoding the first PWM signal and adjusting a speed of a fan module according to the decoded first PWM signal.

4. The fan speed control system of claim 2, wherein the BMC comprises a first comparing unit connected to the temperature sensor; the CPLD comprises a second comparing unit connected to the temperature sensor; and when the BMC operates normally, the first comparing unit reads the detected temperatures, and the second comparing unit reads the detected temperatures when the operation signal receiving pin receives the BMC_fail signal.

5. The fan speed control system of claim 4, wherein each of the first comparing unit and the second comparing unit comprises the preset temperatures.

6. The fan speed control system of claim 4, wherein the second comparing unit is connected to the temperature sensor through an I²C bus.

7. The fan speed control system of claim 4, wherein the CPLD further comprises a decoding and driving unit for decoding the first PWM signal and adjusting the speed of the fan module according to the decoded first PWM signal, and the second comparing unit is connected to the decoding and driving unit.

8. The fan speed control system of claim 7, wherein when the BMC fails to operate normally, the second comparing unit compares each detected temperature with the corresponding preset temperature and sends a second PWM signal to the decoding and driving unit, and the decoding and driving unit decodes the second PWM signal and adjusts the speed of the fan module according to the decoded second PWM signal.

9. The fan speed control system of claim 2, wherein the operation signal receiving pin is connected to the second comparing unit.

10. A fan speed control system, comprising:
a BMC comprising an operation signal sending pin;
a CPLD comprising an operation signal receiving pin connected to the operation signal sending pin; and
a temperature sensor is configured for detecting temperatures of electronic components;
wherein when the BMC operates normally, the temperature sensor sends the detected temperatures to the BMC, and the BMC compares each detected temperature with a corresponding preset temperature and sends a first PWM signal to the CPLD, and the CPLD decodes the first PWM signal and adjusts a speed of a fan module according to the decoded first PWM signal; and when the BMC fails to operate normally, the operation signal sending pin sends a BMC_fail signal to the operation signal receiving pin, the temperature sensor sends the detected temperatures to the CPLD, and the CPLD compares each detected temperature with the corresponding preset temperature and adjusts the speed of a fan module according to a comparing result.

11. The fan speed control system of claim 10, wherein the BMC comprises a first comparing unit connected to the temperature sensor; the CPLD comprises a second comparing unit connected to the temperature sensor; when the BMC operates normally, the first comparing unit reads the detected temperatures; and when the BMC fails to operate normally, the second comparing unit reads the detected temperatures when the operation signal receiving pin receives the BMC_fail signal.

12. The fan speed control system of claim 11, wherein each of the first comparing unit and the second comparing unit comprises the preset temperatures.

13. The fan speed control system of claim 11, wherein the second comparing unit is connected to the temperature sensor through an I²C bus.

14. The fan speed control system of claim 10, wherein the CPLD further comprises a decoding and driving unit for decoding the first PWM signal and adjusting the speed of the fan module according to the decoded first PWM signal or the decoded second PWM signal, and the second comparing unit is connected to the decoding and driving unit.

15. The fan speed control system of claim 14, wherein when the BMC fails to operate normally, the second comparing unit compares each detected temperature with the corresponding preset temperature and sends the second PWM signal to the decoding and driving unit, and the decoding and driving unit decodes the second PWM signal and adjusts the speed of the fan module according to the decoded second PWM signal.

16. The fan speed control system of claim 11, wherein the operation signal receiving pin is connected to the second comparing unit.
